(19) United States
(12) Patent Application Publication
(10) Pub. No.: US 2006/0215447 A1
(43) Pub. Date: Sep. 28, 2006

(54) Asynchronous Memory Array Read/Write Control Circuit

(75) Inventors: PingFu Hsieh, Tainan (TW); HungJu Wang, Tainan (TW); JuiLi Sun, Kaohsiung (TW)

Correspondence Address: BEEDAR TECHNOLOGY INC., R206, #12, NAN-KE 2ND ROAD,, TAINAN SCIENCE-BASED INDUSTRIAL PARK, TAINAN, TW

(73) Assignee: BEEDAR TECHNOLOGY INC., Tainan (TW)

(21) Appl. No.: 10/907,221

(22) Filed: Mar. 24, 2005

(51) Int. Cl. G11C 16/04

(52) U.S. Cl. 365/185.01

(57) ABSTRACT

A non-volatile memory control circuit provides a simple source line/word line generator instead of a complicated decoder. The invention also includes a new design to reduce power consumption for many wireless applications with stable or unstable power source. The selectable multi-characteric global cell is one of advantages of the present invention.

### FILED OF THE INVENTION

The present invention relates to an asynchronous memory array control circuit. The asynchronous control unit is not enabled by an internal or external clock tree. It works and is enabled through determining procedure signals and executes a predetermined operation.

### BACKGROUND OF THE INVENTION

Non-volatile memories are becoming more and more popular because they can store information in the absence of continuous power and also can be constructed in compact form. The control circuit of nonvolatile memory has been developed for many years and the way we're seeing is becoming more and more complicated.

In conventional nonvolatile memory control circuit design, in order to perform erase, program, and read operation, the source line/bit line decoder is employed into control circuit design. Traditionally, the source line/bit line decoder requires high-voltage level-shifter for the pre-coder of the source line/bit line decoder. These types of pre-coders require nearly negative and positive high voltage with large silicon real estate that would complicate the decoder design. Moreover, it may take a lot of time to re-design the whole decoders, even add/reduce a few procedure signals.

Another problem of conventional nonvolatile memory control circuit design is the power consumption. In many wireless applications, the power source may not be stable. The traditional power is supported by power cord or battery source. However, in recent development of wireless device, the power may be induced by resonant EM field. Therefore, it becomes an important task to reduce power consumption in control circuit.

The third problem of conventional nonvolatile memory control circuit design is that almost no one supports multi-program types to satisfy every kind of applications. For instance, there are two major methodologies of program; one is channel hot electron (CHE) injection, and the other is FN-tunneling. Theoretically, the most popular way of program method is CHE injection because of the speed of response. In contrary, the CHE injection wastes more power than any other methods.

Finally, due to manufacturing variation, the characteristic of memory may be different lot by lot. Thus, it may not be adequate to use a single characterized global cell to prevent unpredictable fluctuation of manufacturing.

The goals of the invention are to overcome the above identified problems of conventional nonvolatile memory control circuit design and to provide a new design for non-volatile memory control circuit.

### SUMMARY

The invention overcomes the conventional source line/bit line decoder design problems. The new design of the invention, namely is called “source line/bit line generator”. The generator comprises a plurality of units coupled to memory array. Each unit includes a separate logic operation and high-voltage level-shifter. The advantage of this design can provide easy modification without changing high-voltage level-shifter design.

The second advantage of the invention is reduced power consumption of conventional non-volatile memory control circuit design by applying single sense amplifier and provide single bit asynchronous memory data output. The second advantage of the invention is to reduce power consumption, and maintains VDD when high-voltage VPP or VPP2 is not applied. Because of the new design of high voltage generators, the invention can provide three types of programmed modes by applying CHE injection and FN-tunneling technology. Unlike the traditional non-volatile memory, the novel control circuit design is using single global cell to determine the value of selected bit. The invention provides selectable characterized global cells for reference current.

### BRIEF DESCRIPTION OF THE DRAWINGS

FIG. 1 depicts a block diagram, including a memory array as well as an embodiment of the invention.

FIG. 2 depicts a single transistor structure of memory cell.

FIG. 3 depicts a time table of procedure signals in read mode.

FIG. 4 depicts a conventional memory array.

FIG. 5 depicts a block diagram of high voltage generator 1.

FIG. 6 depicts a block diagram of high voltage generator 2.

FIG. 7 depicts an internal component of source line generator of FIG. 1.

FIG. 8 depicts logic operation of procedure signals of source line generator.

FIG. 9 illustrates a flow chart of operations of source line generator.

FIG. 10 depicts an internal component of bit line generator of FIG. 1.

FIG. 11 depicts logic operation of procedure signals of bit line generator in PROGRAM 1 and PROGRAM 3 mode.

FIG. 12 depicts logic operation of procedure signals of bit line generator in PROGRAM 2 mode.

FIG. 13 illustrates a flow chart of operations of bit line generator.

FIG. 14 illustrates a procedure flow chart of BLEN generator output signal READEN.

FIG. 15 depicts a block diagram of sense amplifier.

FIG. 16A-C shows three different structures of global cell.

FIG. 17 depicts multi-global cell structure and equivalent bit line loading paths.

FIG. 18 illustrates a flow chart of asynchronous memory array read write control circuit.

### DETAILED DESCRIPTION

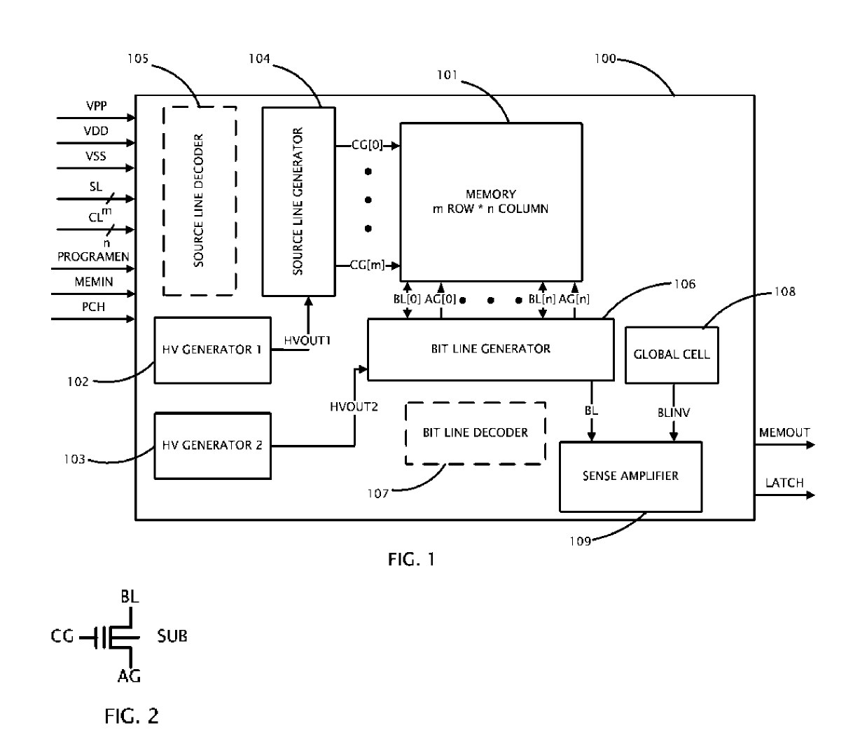

FIG. 1 depicts an arrangement of embodiment 100 of invention wherein includes a m*n memory array 101, a source line generator 104, a bit line generator 106, a sense amplifier 109, a global cell 108, and two high voltage generators 102 and 103. The source line decoder 105 and bit line decoder 107 may or may not be necessary to be applied in the present invention or in the feature, respectively. The global cell 108 is applied to sense amplifier 109. The global cell is set to be an independent cell either in program or erase state. The BLINV comes from global cell 108 and BL comes from the bit line generator 106. Both of these signals are manipulated in the sense amplifier 109 and comparing with each other in current to determine 0 or 1 logically. The final result is delivered out through MEMOUT.

The high voltage generator1 102 supports voltage for source line generator 104 and high voltage generator2 103 for bit line generator 106. Both of the high voltage generators output HVOUT1 and HVOUT2 may or may not have the equal operations. It depends on the requirements of memory cell.

Due to larger numbers of memory cell, the source line decoder 105 and bit line decoder 107 are applied to source line 104 and bit line generator 106 respectively, and finally to memory array. According to the larger number of memory cells, this invention can be scaled to arbitrary dimension of memory array conveniently with less investment. Therefore, the total source line terminal will become 2^{m} with respect to input signal, SL [0:m].

FIG. 2 depicts a single memory bit cell structure. The table 1 demonstrates the parameters in the operations of erasing, reading, and programming. The erase scheme is normally employed in channel FN-tunneling. The program schemes are available in either CHE (Channel-Hot-Electron) injection or channel FN-tunneling. The channel FN-tunneling scheme for program also has two conditions which are imposed on drain (BL) and source (AG) terminals of cells. The major differences between CHE injection and channel FN-tunneling in program schemes are program/erase duration and power consumption. Theoretically, the former of cells utilizing CHE injection is much faster than FN-tunneling. However, according to the later, the cell with CHE injection mechanism consumes more power.

There is a two transistors memory structure may also be employed in above program/erase methodologies. The source of conventional MOS device, called selector couples to the drain of memory cell. The control signal is imposed on the gate of selector.

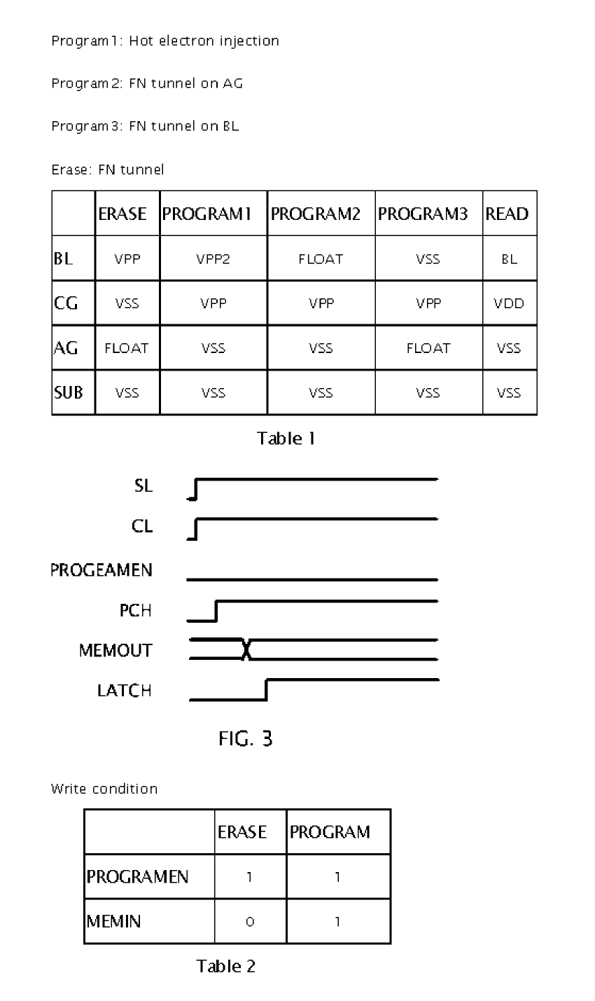

FIG. 3 shows an important feature of invention that the embedded memory has an asynchronous single bit output. According to the time diagram during read mode, the address line, for instance, SL and CL to identify the selected bit. The input signal triggers the memory array to send the data out through data path, MEMOUT. The latch signal ensures control unit to receive correct data in the path, MEMOUT.

Table 2 demonstrates the input procedure signals PROGRAMEN and MEMIN in write mode. The significant difference of invention is the multi-bit synchronous MEMIN versus single-bit asynchronous MEMOUT. It means that memory can be erased and programmed by bit, byte, block, and whole array. However, there is only ONE bit available to be read in read operation.

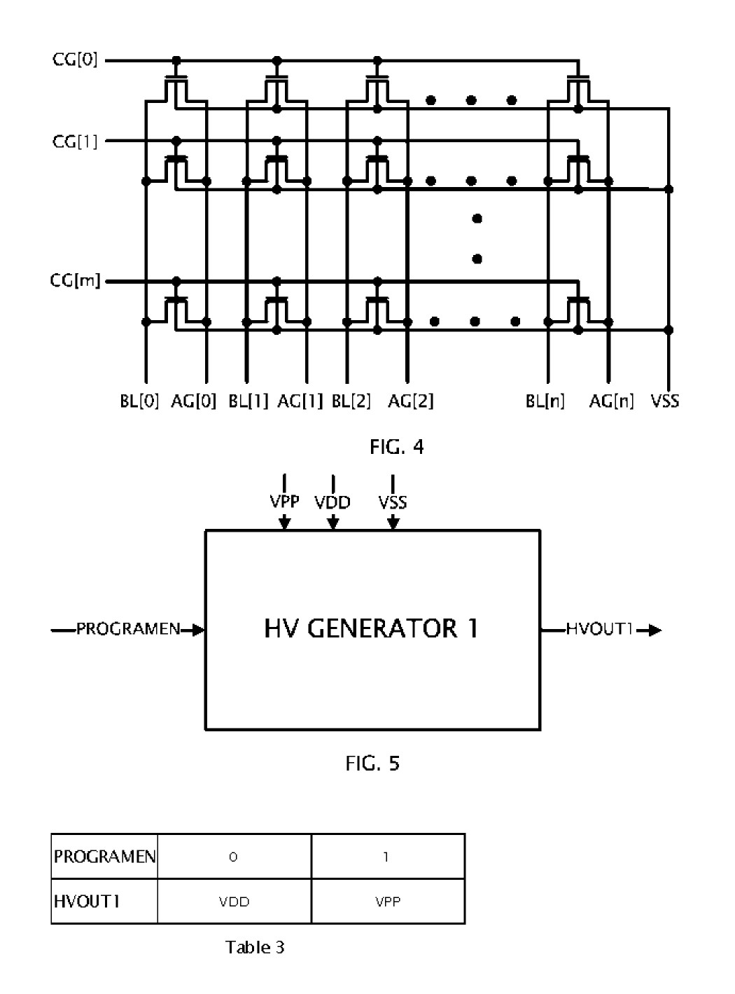

FIG. 4 depicts a memory array. It is very clear wherein each source line connected to separate bit line cells. In the same way, each bit line connected to separate source line cells. For n-channel devices, the CG0-CGm is applied to the source line generator to select the specific row. Further, BL0-BLn is coupled to bit line generator to identify selected bit. The configurations of erase, program, and read operation are shown on Table 1.

FIG. 5 depicts one of two high voltage generators. The high voltage generator is used to generate enough voltage to execute program or erase command. In the present invention, the HV generator1 supports power for source line generator. According to table3, HVOUT1 is equal to VDD/VPP when PROGRAMEN is 0/1.

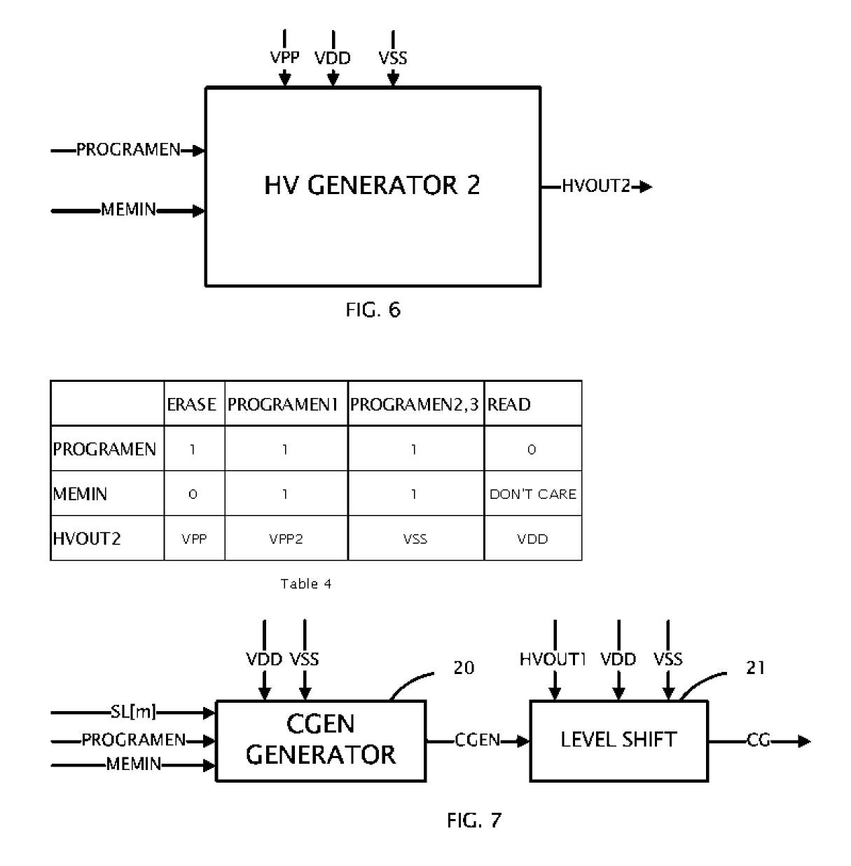

FIG. 6 depicts another high voltage generator in this invention. The role of HV generator2 is used to support bit line generator with sufficient power. A few differences between both of HV generators are shown as following. First, the input signal MEMIN delivers logic 0 or 1 to bit line generator and the value to be written in selected bit by cooperating with source line generator. Second, an important feature of present invention, the HV generator2 not only generates VPP but VPP2. Please refer to Table 1. For erase and program operations, VPP is higher than VPP2, which is higher than VDD.

FIG. 7 depicts a single path of source line generator. Please refer to FIG. 1. In an m*n memory array, m signals from CG0 to CGm are outputs of source line generator. In order to identify any bit in the memory array, row identifiers SL [0:m] and column identifiers CL [0:n] are necessary. Once the specific row is determined, one of row identifiers SL enables CGEN generator to deliver CGEN.

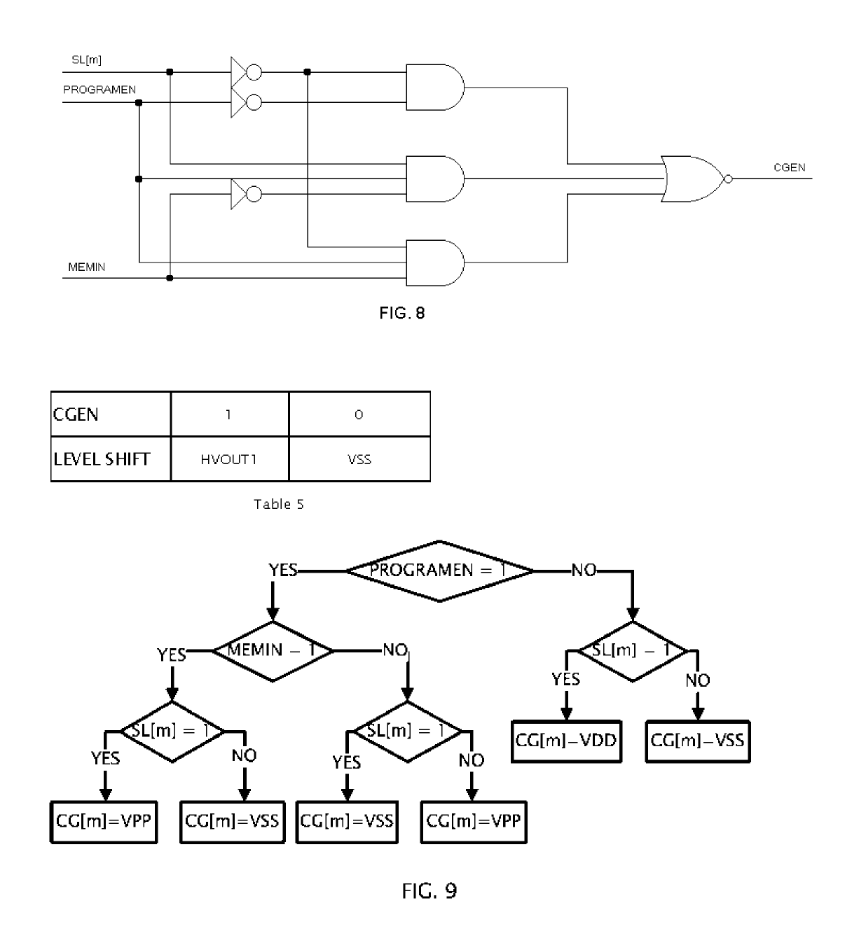

FIG. 8 demonstrates the whole logic operation and determination of procedure signals. An important feature of invention is to separate logic and high voltage blocks. It becomes more convenient to modify procedure signals without re-designing high voltage circuit.

Comprising the operated parameters of Table 1, Table 2, Table 3, and Table 5, it executes commands of erasing, programming, and reading functions for selecting the row of array.

FIG. 8 is a flowchart showing the operation procedure of source line generator.

FIG. 9 depicts a flowchart of source line operation.

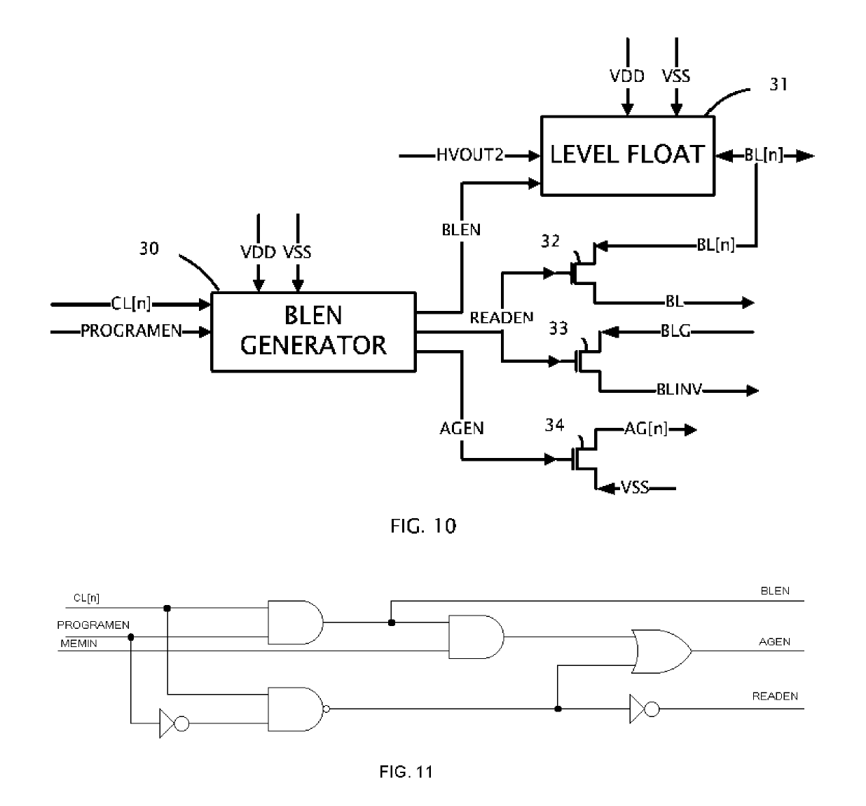

FIG. 10 depicts a single path of bit line generator. Please refer to FIG. 1. In an m*n memory array, n signals from CL0 to CLn are outputs of bit line generator. As mentioned above, Once the specific column is determined, one of bit line path CL enables BLEN generator to deliver BLEN signal. According to the value of BLEN, the output BL of level floating will be either HVOUT2 or floating. Meanwhile, base upon pre-determined CL [0:n], the READEN turns both of BL [0:n] and BLG on. The BL0-BLn is connected to each column. The selected BL is determined by CL. If the READEN is turned on, both of BL and BLG enter the successive sense amplifier to be compared. BLEN also generates AGEN to perform erase, program, and read commands.

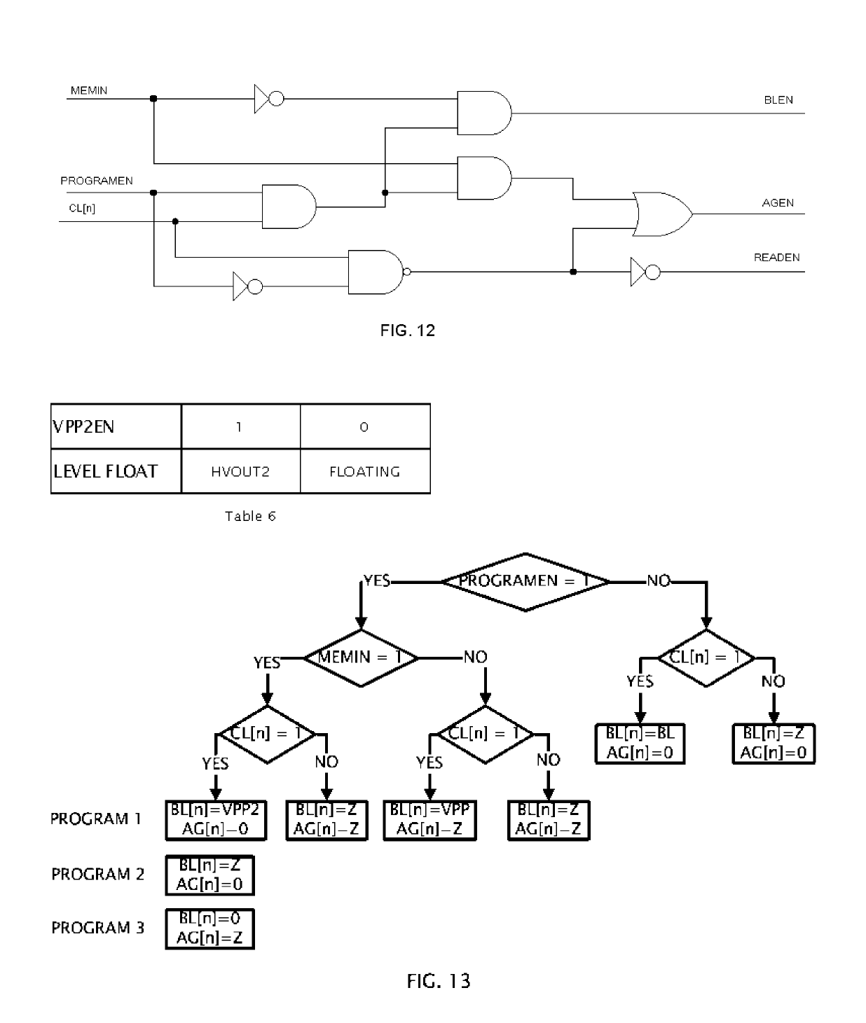

Referring to Table 1, the invention includes three programmed modes. FIG. 11 and FIG. 12 depict logistic path to determine one of programmed modes. FIG. 11 demonstrates PROGRAM1 and PROGRAM3 mode. FIG. 12 demonstrates PROGRAM2 mode. Comprising the operated parameters of Table 1, Table 2, Table 3, and Table 6, it will execute commands of erasing, programming, and reading functions for selecting the column of array.

FIG. 13 is a flowchart showing the operating procedure of bit line generator.

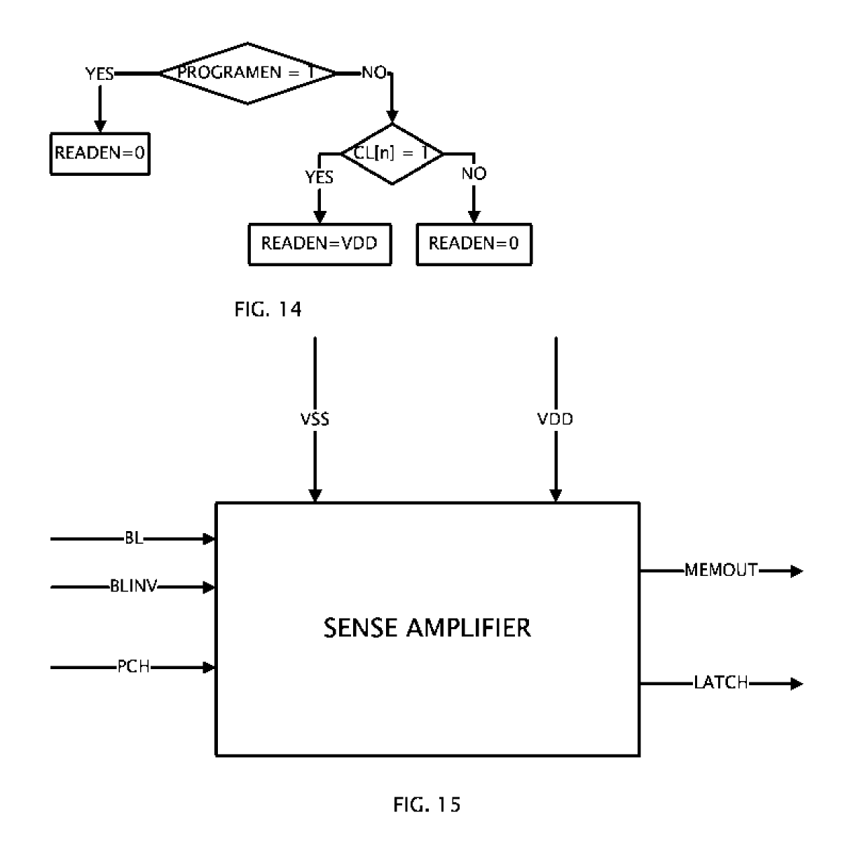

FIG. 14 is a flowchart showing operation of READEN. The memory is either erasing or programming when PROGRAMEN=1. Thus, READEN is low to turn switches off. On the contrary, the both of BL and BLINV are turned on when bit line CL is selected to output data. FIG. 15 depicts the structure of sense amplifier. The purpose of sense amplifier is used for the value of selected bit. The BL comes from bit line generator and BLINV from global cell. The PCH is one of procedure signals and plays the role of triggering the sense amplifier. The value after comparison sends out through MEMOUT. Technically, latch is going to synchronize MEMOUT. Moreover, in this invention, the latch signal is a trigger for outside control circuit to get the ready data in MEMOUT. Thus, it is to be delayed in a certain time behind MEMOUT to secure the correct data.

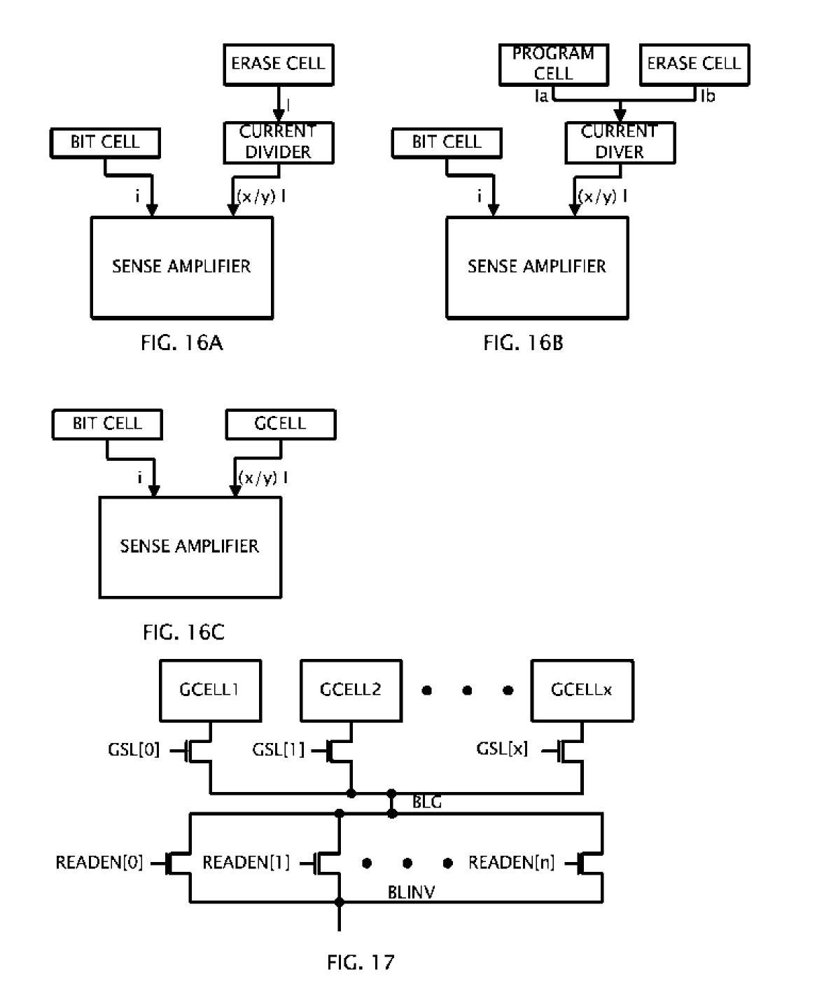

FIG. 16A-C depicts three different ways to create reference current level. The integer x≦y and parameter i≦I. “I” means the current of erase cell or sum of program cell and erase cell current. Theoretically, the bit cell current “i” is either near program cell current “Ia” or erase cell current “Ib”. The ideal current (x/y)*I is in the middle of window of all bit cell current for determining logic 1/0 by sense amplifier. In FIG. 16A, the erase cell has the maximum current, and is coupled to current divider to create variable current source. In FIG. 16B, “I” is coupled to current divider to create variable current source. In FIG. 16C, the global cell comprises dividing current methodology to create the current source of reference current.

FIG. 17 depicts the structure about global cells. Please refer to FIG. 11. The sense amplifier is used for determining the readout value of select bit. In the invention, the value is determined by the different current between BL and BLINV. It is necessary to split BLG current into the same numbers of bit line paths to ensure the BLINV current to have the approximate loading as BL. Another important feature of invention is the selectable global cells. It may or may not be employed into present invention. According to experimental and physical reports, memory cell always fatigues in endurance and data retention as the time it is used. Sooner or later, the sense amplifier may not be able to tell the correct value of selected bit. Therefore, it may extend operating reliability of memory cell by selecting proper characteristic global cell and to stream out the correct value.

There are two topologies to make suitable global cell to generate the dynamic reference current. One is to adjust the SPICE parameters, W/L of cells to gain adapted current. The other is to tune discharge/charge time of cell. For example, it approximately needs 0.3 ms to gain half current level if it needs 1 ms to discharge a cell. It depends on the practical characteristics of cell to set charge and discharge time.

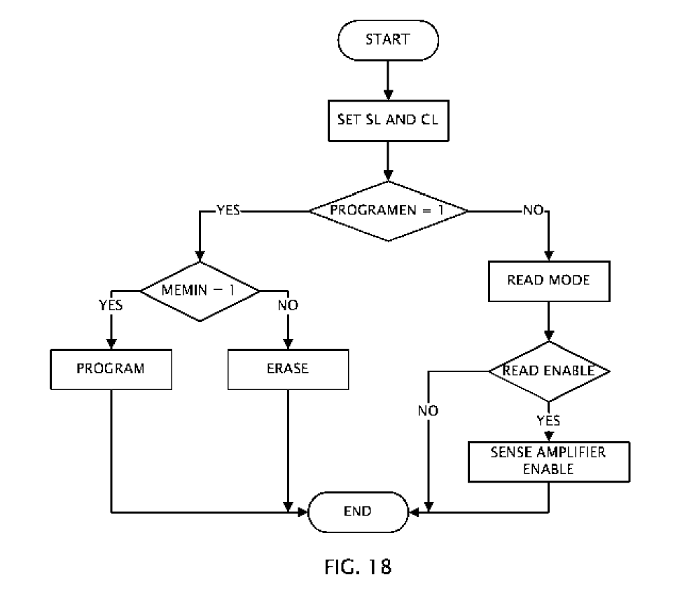

FIG. 18 depicts a flowchart wherein demonstrates procedures of asynchronous memory array control circuits.

What is claimed is:

1. An asynchronous memory control circuit comprising:
a plurality of source line terminals to be adapted to multiple memory words;
a plurality of bit line terminals to be adapted to multiple memory bits;
a twin voltage terminal to receive and generate multi-voltage sources;
a single sense amplifier to receive single memory cell data;
a procedure terminals to receive procedure signals;
a global cell to provide base current source.

2. An asynchronous memory control circuit of claim 1, wherein:
said source line terminals include a plurality of source line generator coupled to each, said source line or row of memory array, said to provide voltage simultaneously to source line to accomplish a predetermined operating signal, said procedure signal.

3. An asynchronous memory control circuit of claim 1, wherein:
a source line terminals coupled to, said a source line decoder to support a, said large numbers of memory cell; and said the procedure signals coupled to source line decoder to accomplish a predetermined operating signals, said procedure signals; and said to provide voltage simultaneously.

4. An asynchronous memory control circuit of claim 1, wherein:
said bit line terminals includes a plurality of bit line generators coupled to each, said bit lines or columns of memory array, said to provide voltage simultaneously to bit line to accomplish a predetermined operating signal, said procedure signals.

5. An asynchronous memory control circuit of claim 1, further comprising:
a bit line terminals coupled to, said a bit line decoder to support a, said large numbers of memory cell; and said the procedure signals coupled to bit line decoder to accomplish a predetermined operating signals, said procedure signals; and said to provide voltage simultaneously.

6. An asynchronous memory control circuit of claim 1, wherein:
said a high voltage generator coupled to, said two voltage sources, said part of procedure signals to said to determine the output voltage source coupled to, said source line or bit line generator/decoder.

7. An asynchronous memory control circuit of claim 1, wherein:
said a single asynchronous sense amplifier instead of conventional multi-sense amplifier coupled to procedure signals, said bit line terminals and said, global cell; and
said to reduce power consumption is compatible with, said RFID application.

8. An asynchronous memory control circuit of claim 1, wherein:
said a single global cell to provide current to, said sense amplifier to compare the current level with said bit line current source; and said a single global cell can extend to said multi-global cells to provide different level current sources.

9. An asynchronous memory control circuit of claim 1, further comprising:
said source line generator comprises said logic wherein be modified easily to be adapted different procedure signals and high voltage device wherein supports multi-input voltage and generates, said single voltage output.

10. An asynchronous memory control circuit of claim 1, further comprising:
said bit line generator comprises said logic wherein be modified easily to be adapted different procedure signals and high voltage device wherein supports multi-input voltage and generates, said single voltage output, and said multi-control switch output.

11. An asynchronous memory control circuit of claim 1, further comprising:
a two transistors structure of memory cell may wherein said replaces a single conventional transistor memory cell, and said extra control path of selector transistor coupled to said source line generator.

12. The method to perform erased and programmed function in present invention of asynchronous memory array, comprising:
a method of erase and program by bit;
a method of erase and program by block;
a method of erase and program by whole memory array;
a method of erase and program by fixed source line selected block and arbitrary bit line selected bit;
a method of erase and program by fixed bit line selected bit and arbitrary source line selected block.
